(19) United States
(12) Patent Application Publication
(10) Pub. No.: US 2024/0079450 A1
(43) Pub. Date: Mar. 7, 2024

(54) HETEROJUNCTION BIPOLAR TRANSISTOR STRUCTURE HAVING CURRENT CLAMPING LAYER

(71) Applicant: VISUAL PHOTONICS EPITAXY CO., LTD., Taoyuan City (TW)

(72) Inventors: Yu-Chung CHIN, Taoyuan City (TW); Zong-Lin LI, Taoyuan City (TW); Chao-Hsing HUANG, Taoyuan City (TW)

(21) Appl. No.: 18/240,364

(22) Filed: Aug. 31, 2023

(30) Foreign Application Priority Data
Sep. 1, 2022 (TW) 111133250

(51) Int. Cl. H01L 29/08; H01L 29/205; H01L 29/737

(52) U.S. Cl. CPC H01L 29/0821; H01L 29/205; H01L 29/7371

(57) ABSTRACT

A heterojunction bipolar transistor structure is provided, including a substrate and a multi-layer structure formed on the substrate. The multi-layer structure includes a current clamping layer, and the current clamping layer can be disposed in a collector layer, disposed in a sub-collector layer, or interposed between a collector layer and a sub-collector layer. An electron affinity of the current clamping layer is less than an electron affinity of an epitaxial layer formed on the current clamping layer.

### CROSS-REFERENCE TO RELATED APPLICATION

This application claims priority to Taiwan Application Serial Number 111133250, filed Sep. 1, 2022, which is herein incorporated by reference in its entirety.

### BACKGROUND

### Field of Invention

The present invention relates to a heterojunction bipolar transistor structure, and more particularly, to a heterojunction bipolar transistor structure having a current clamping layer.

### Description of Related Art

The heterojunction bipolar transistors (HBTs) use different semiconductor materials to form the emitter and the base layers and form a heterojunction at the junction of the emitter and the base. The advantage is that the emitter injection efficiency increases because the hole flowing from the base to the emitter is more difficult to cross the valence band offset (AEv) between the base and the emitter, especially when the emitter is made of InGaP, InGaAsP, or InAlGaP, and the valence band hole barrier of the emitter and the base is particularly large. As a result, the HBT can maintain high current gain and improve high frequency response with high base doping concentration. When the HBT is used as a power amplifier (PA) for a handheld device, the power added efficiency (PAE) is particularly important. On the HBT device, in addition to improving the PAE by adjusting the HBT epitaxial layer structure, the operating voltage or current modification of the PA by circuit design can also effectively improve the PAE. However, when the HBT operates at a high voltage or a high current, the HBT is prone to damage due to excessive power. For example, the excessive power rebounded back when the PA is not in the impedance match condition and causes the ruggedness issue of the HBT. Therefore, how to effectively improve the ruggedness of an HBT under high voltage or high current (i.e., high power density) operation is an important topic.

U.S. Patent Publication Number 6806513 (hereinafter referred to as the 513 patent) discloses “a layer of wider bandgap material is inserted at the collector-subcollector junction to thereby increase the breakdown voltage . . . ”, and “FIG. 3 illustrates one embodiment of the invention in which an N-doped AlGaAs wide bandgap (relative to GaAs) layer 34 is inserted in the collector structure and abuts N⁺ GaAs subcollector layer 12. The dopant concentrations can be on the order of 7×10¹⁵/cm³ for the collector and insertion layer and 4×10¹⁸/cm³ for the subcollector. The wide bandgap insertion layer should be kept thin relative to the total collector layer thickness.”. “In one embodiment collector layer 14 is 2.5 μm in thickness and the insertion layer 34 is 0.5 μm in thickness.”.

However, while the HBT is operating in safe operating area (operating under normal current density), the insertion layer actually blocks many electrons. This resulting in an increase in the knee voltage of HBT, subsequently affecting the efficiency and high-frequency characteristics of the HBT.

### SUMMARY

In one embodiment, the current clamping layer is disposed between the sub-collector layer and the collector layer, and an electron affinity of the current clamping layer is less than an electron affinity of the collector layer. This creates an appropriate electronic barrier at the interface between the current clamping layer and the collector layer.

In one embodiment, the current clamping layer is disposed in the collector layer. If the collector layer consists of two layers and the current clamping layer constitutes the lower portion of the collector layer (adjacent to the sub-collector layer), the electron affinity of the current clamping layer is less than the electron affinity of the upper portion of the collector layer, that is, the electron affinity of the current clamping layer is smaller (compared to the upper portion of the collector layer), and the electron affinity of the upper portion of the collector layer is larger (compared to the current clamping layer). If the collector layer includes three layers and the current clamping layer constitutes the middle portion of the collector layer, the electron affinity of the current clamping layer is less than the electron affinity of the uppermost portion of the collector layer, that is, the electron affinity of the current clamping layer is lower (compared to the uppermost portion of the collector layer), while the uppermost portion of the collector layer has higher electron affinity (compared to the current clamping layer). This creates an appropriate electronic barrier at the interface between the current clamping layer and the uppermost portion of the collector layer.

In one embodiment, the current clamping layer is disposed in the sub-collector layer, wherein the sub-collector layer is doped with a low doping concentration. Preferably, the current clamping layer is disposed in the sub-collector layer and adjacent to the collector layer. If there is “one portion of the sub-collector layer” is formed on the current clamping layer, the electron affinity of the current clamping layer is less than the electron affinity of the “the one portion of the sub-collector layer”. This creates an appropriate electronic barrier at the interface between the current clamping layer and the “the one portion of the sub-collector layer”.

The so-called “appropriate electronic barrier” refers to a situation where, when the HBT is operating in the safe operating area (SOA) or under typical current density, although the current clamping layer has electron barrier, the electrons still can pass through the current clamping layer with relatively less hindrance. When the HBT is operated at a high power density or a high current density, the electron barrier of the current clamping layer increases with the rise in current density. This prevents excessive current from flowing into the collector layer, thereby enhancing the ruggedness of the PA. However, a considerable amount of current is blocked by the HBT of the 513 patent when the HBT is operated at low current density, so it is difficult to operate the HBT in the active region.

### BRIEF DESCRIPTION OF THE DRAWINGS

The invention can be more fully understood by reading the following detailed description of the embodiment, with reference made to the accompanying drawings as follows:

FIG. 1a is a schematic diagram of an HBT structure according to the first embodiment;

FIG. 1b-1e are schematic diagrams of different relationships between the conduction band of the current clamping layer and the collector layer;

FIG. 2a is a schematic diagram of an HBT structure according to the second embodiment;

FIG. 2b is a schematic diagram of an exemplary conduction band configuration of FIG. 2a;

FIG. 3a is a schematic diagram of an HBT structure according to the third embodiment;

FIG. 3b is a schematic diagram of an exemplary conduction band configuration of FIG. 3a;

FIG. 4a is a comparison diagram showing the common emitter I-V characteristics of an HBT with the AlGaAs insertion layer and an HBT without the AlGaAs insertion layer;

FIG. 4b is a schematic diagram of the conduction band of an current clamping layer with an Alₓ₁Ga₁₋ₓ₁As insertion layer and an Alₓ₂Ga₁₋ₓ₂As graded layer;

FIGS. 5a-5b are comparison diagram showing the common emitter I-V characteristics of seven different HBTs;

FIG. 5c is a schematic diagram of the conduction band of the Alₓ₃Ga₁₋ₓ₃As current clamping layers of groups 2;

FIG. 5d is a schematic diagram of the conduction band of the Alₓ₆Ga₁₋ₓ₆As current clamping layer of group 5; and

FIG. 5e is a schematic diagram of the conduction band of the Alₓ₇Ga₁₋ₓ₇As current clamping layer and the conduction band of the Alₓ₈InGaP current clamping layer of group 6.

### DETAILED DESCRIPTION

The embodiment of the present invention is described in detail below with reference to the drawings and element symbols, such that persons skilled in the art is able to implement the present application after understanding the specification of the present invention.

Specific examples of components and arrangements are described below to simplify the present invention. Of course, these are merely examples and the examples are not intended to limit the scope of the present invention. For example, when a description refers to one layer above another, it may include embodiments where the layer is in direct contact with the other layer or may include embodiments where other elements or epitaxial layers are formed between the two layers and the two layers are not in direct contact. In addition, repeated reference numerals and/or notations may be used in different embodiments, these repetitions are used to describe some embodiments simply and clearly and do not represent a specific relationship between the different embodiments and/or structures discussed.

Further, spatially relative terms, such as “underlying,” “below,” “lower,” “overlying,” “above,” “upper” and the like, may be used herein for ease of description to describe one element or feature's relationship to another element(s) or feature(s) as illustrated in the figures and/or drawings. The spatially relative terms are intended to encompass different orientations of the device in use or operation in addition to the orientation depicted in the figures.

The description of the present invention provides different embodiments to illustrate the technical features of different implementations. For example, “some embodiments” referred to throughout the specification means that the specific features, structures, or characteristics described in the embodiments are included in at least one embodiment. Thus, appearances of the phrase “in some embodiments” in different passages throughout the specification are not necessarily the same embodiments.

Furthermore, the particular features, structures, or characteristics may be combined in any suitable manner in one or more embodiments. Further, for the terms “including”, “having”, “with”, “wherein” or the foregoing transformations used herein, these terms are similar to the term “comprising” to include corresponding features.

In addition, a “layer” may be a single layer or a plurality of layers; and “a portion” of an epitaxial layer may be one layer of the epitaxial layer or a plurality of adjacent layers.

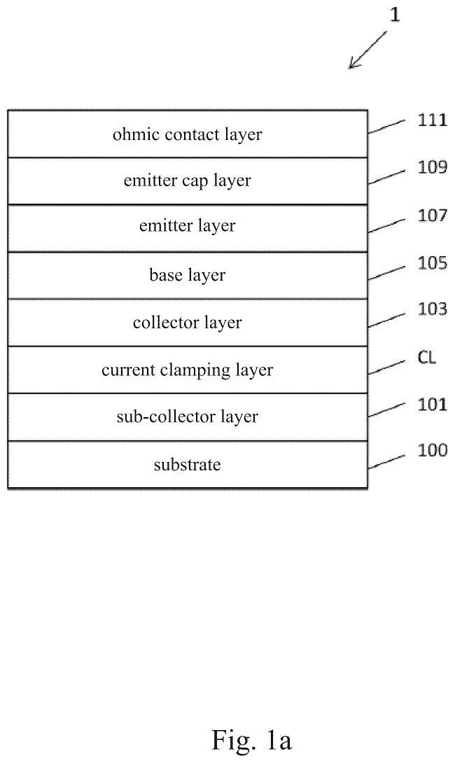

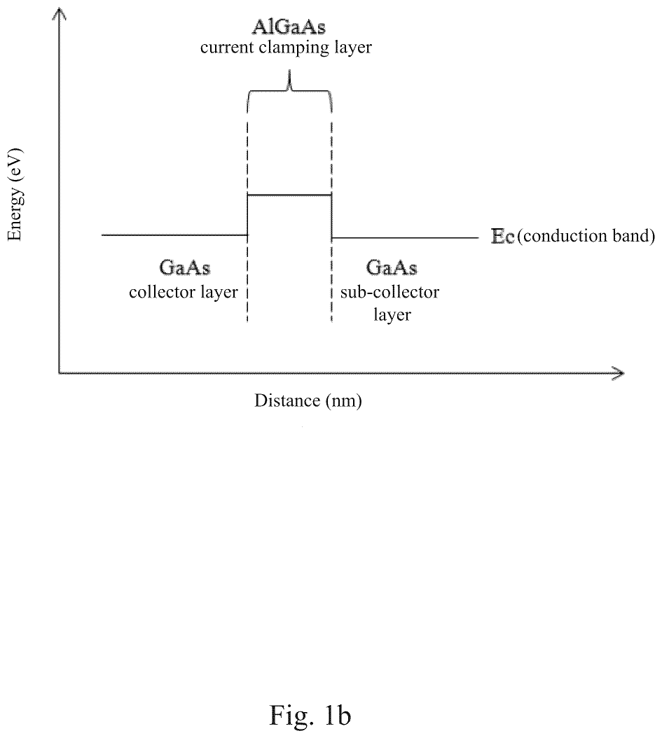

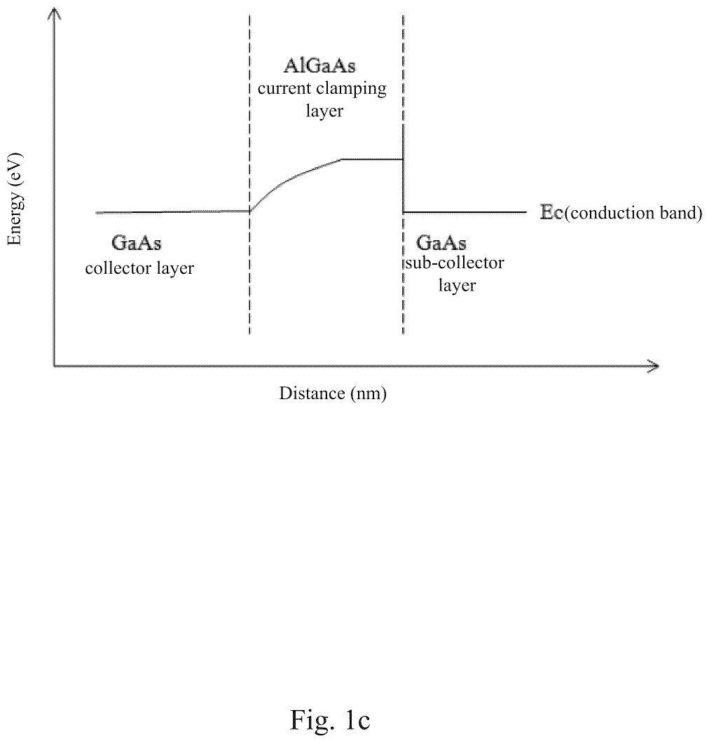

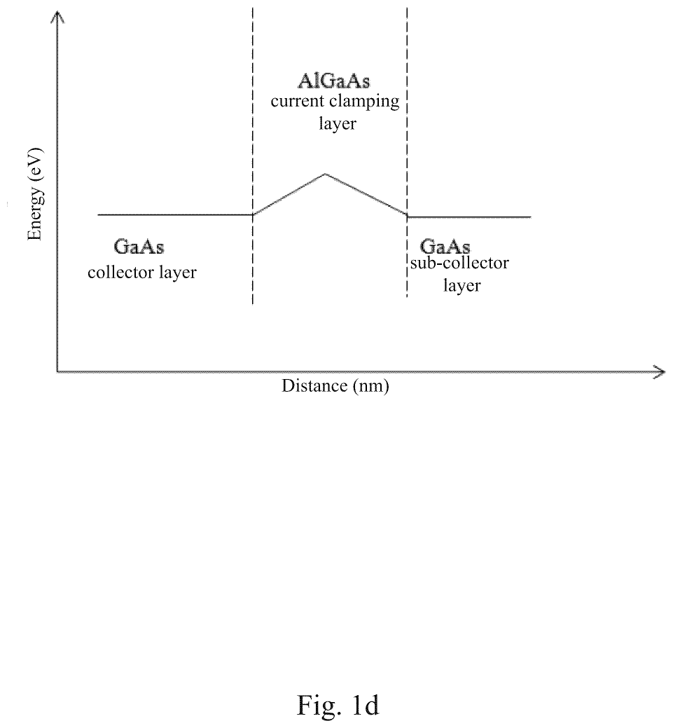

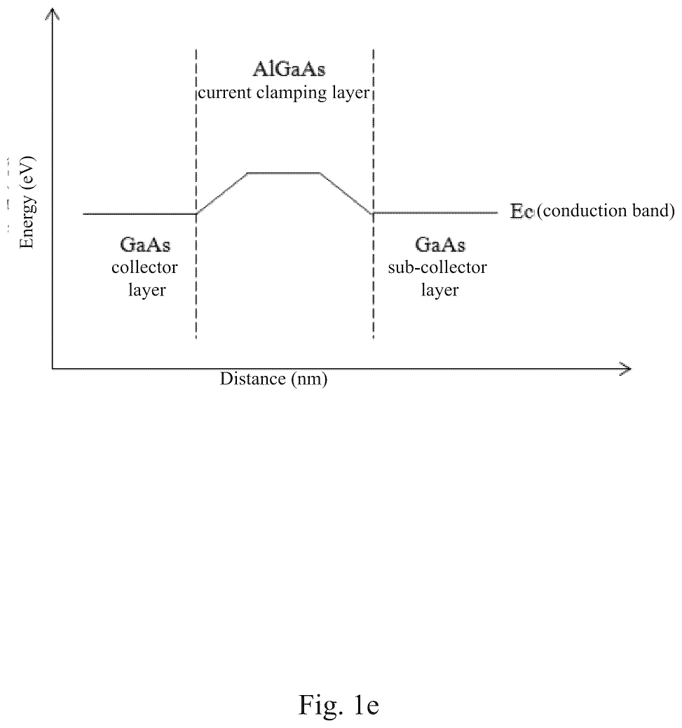

FIG. 1a is a schematic diagram of an HBT structure 1 according to a first embodiment. As shown in FIG. 1a, the HBT structure 1 of the first embodiment includes the epitaxial growth of sub-collector layer 101, a current clamping layer CL, a collector layer 103, a base layer 105, an emitter layer 107, an emitter cap layer 109, and an ohmic contact layer 111 on a substrate 100.

As shown in FIG. 1a, the current clamping layer CL is disposed between the GaAs sub-collector layer 101 and the GaAs collector layer 103, and the electron affinity of the current clamping layer CL is less than the electron affinity of the collector layer. Thereby, an appropriate electronic barrier is formed at the interface between the current clamping layer CL and the GaAs collector layer 103.

The current clamping layer CL includes at least one material selected from the group consisting of AlₓGa₁₋ₓAs, AlGaAsN, AlGaAsP, AlGaAsSb, InAlGaAs, GaAsSb, InGaP, InAlGaP, GaAsPSb, and GaSbP, wherein x is 0.05 to 0.4. The n-type doping concentration of the current clamping layer CL may be from 8×10¹⁵/cm³ to 2×10¹⁸/cm³ from 1×10¹⁷/cm³ to 5×10¹⁷/cm³, or from 2×10¹⁷/cm³ to 5×10¹⁷/cm³. The thickness of the current clamping layer CL may be from 100 Å to 10000 Å, from 100 Å to 5000 Å, or from 100 Å to 2000 Å.

By setting the electron affinity of the current clamping layer CL less than that of the GaAs collector layer 103, the electron barrier of the current clamping layer CL will become higher when the transistor is operated at higher current density. This prevents excessive current from flowing into the collector layer, thereby improving the ruggedness of the PA when operating at high power density. The electron barrier of the current clamping layer CL becomes higher as the current density increases. The magnitude of the increase in the electron barrier may vary depending on the material, thickness, material composition ratio, doping concentration or doping method (such as doping profile) of the collector layer 103, the current clamping layer CL, or the sub-collector layer 101.

FIGS. 1b-1e are schematic diagrams of different relationships between the conduction band of the current clamping layer and the collector layer. FIGS. 1a-1d show that current clamping layers with different conduction band configurations formed between the collector layer and the sub-collector layer. Generally, as long as the electron affinity of at least a portion of the current clamping layer is less than the electron affinity of the collector layer, even if the electron affinity of the other portion of the current clamping layer is greater than or equal to the electron affinity of the collector layer, the current clamping layer can still provide the current clamping function.

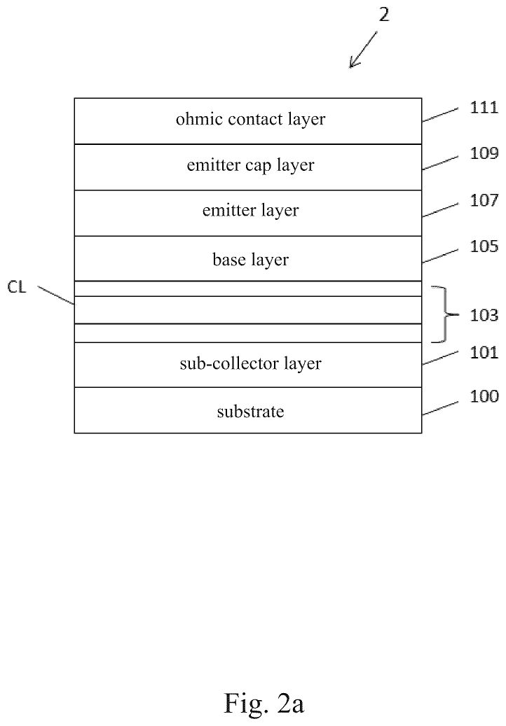

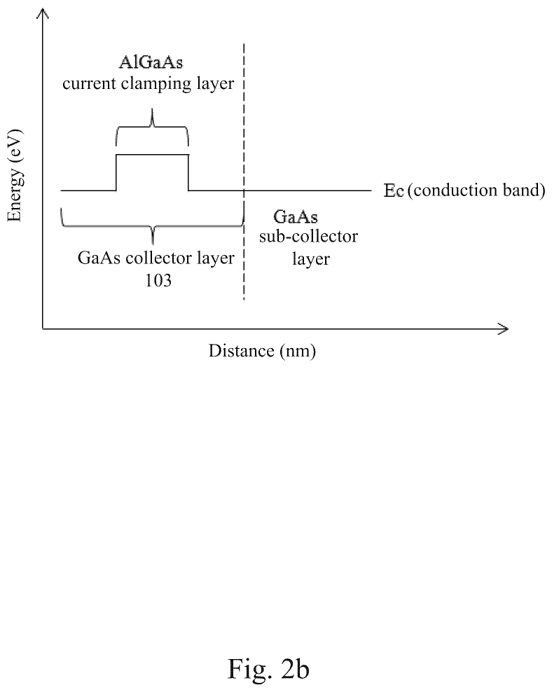

FIG. 2a is a schematic diagram of an HBT structure 2 according to a second embodiment. As shown in FIG. 2a, the current clamping layer CL can also be interposed in the collector layer 103. The collector layer 103 in FIG. 2a includes three layers, and the current clamping layer CL served as the middle portion of the collector layer 103, and the electron affinity of the current clamping layer CL is less than the electron affinity of the uppermost layer of the collector layer 103. The uppermost portion of the collector layer 103 is between the base layer 105 and the current clamping layer CL. FIG. 2b is a schematic diagram of the relationship between the conduction band of the current clamping layer CL and the conduction band of the uppermost layer of the collector layer 103 of FIG. 2a. The bandgaps of the current clamping layer CL in FIG. 2b include gradually-increasing bandgap, gradually-decreasing bandgap, constant bandgap, or combinations thereof, as shown in FIGS. 1c-1e. However, FIGS. 1c-1e are exemplary embodiments and are not limited thereto.

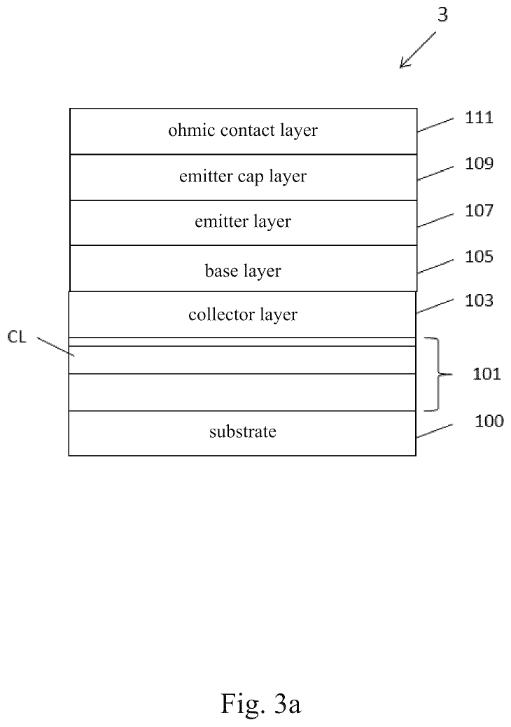

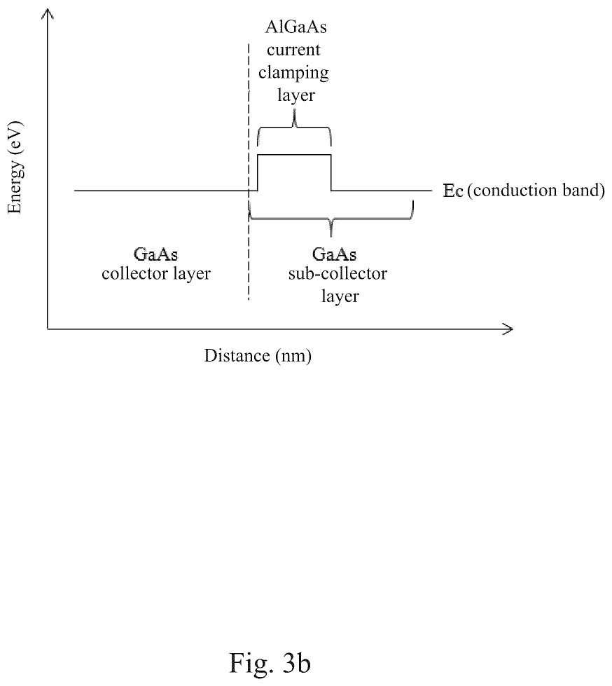

FIG. 3a is a schematic diagram of an HBT structure 3 according to a third embodiment. The doping concentration of the sub-collector layer 101 is of low doping concentration, such as being lower than 3×10¹⁸/cm³. Preferably, the current clamping layer CL is disposed in the sub-collector layer 101 and adjacent to the collector layer 103. If there is “one portion of the sub-collector layer” is formed on the current clamping layer CL, the electron affinity of the current clamping layer CL is set to be less than that of the “the one portion of the sub-collector layer”. This results in a suitable electron barrier at the interface between the current clamping layer CL and the “the one portion of the sub-collector layer”. FIG. 3b is a schematic diagram of the relationship between the conduction band of the current clamping layer CL and the conduction band of the “the one portion of the sub-collector layer (that is, the uppermost layer of the sub-collector layer 101)” of FIG. 3a. The bandgaps of the current clamping layer CL in FIG. 3b also include gradually-increasing bandgap, gradually-decreasing bandgap, constant bandgap, or combinations thereof, as shown in FIGS. 1c-1e. However, FIGS. 1c-1e are exemplary embodiments and are not limited thereto.

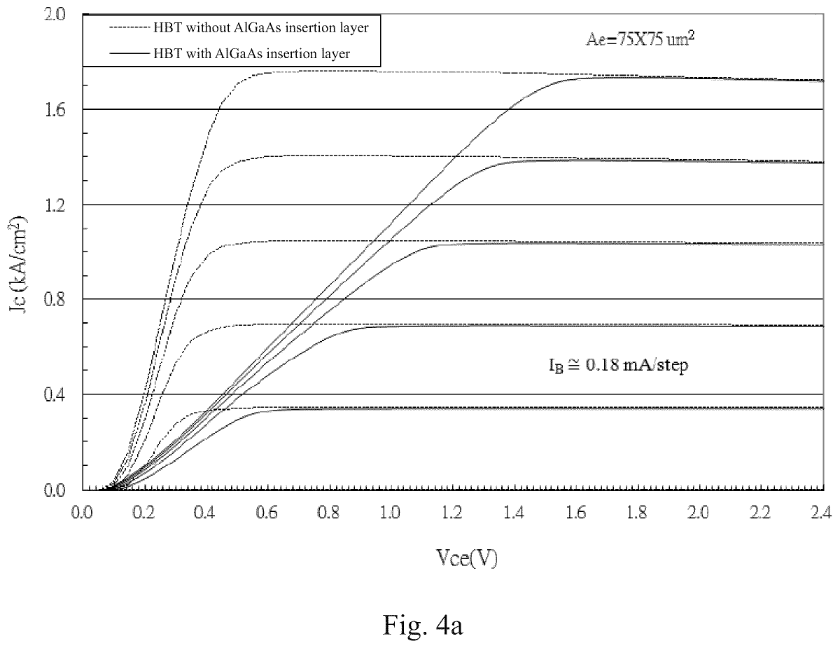

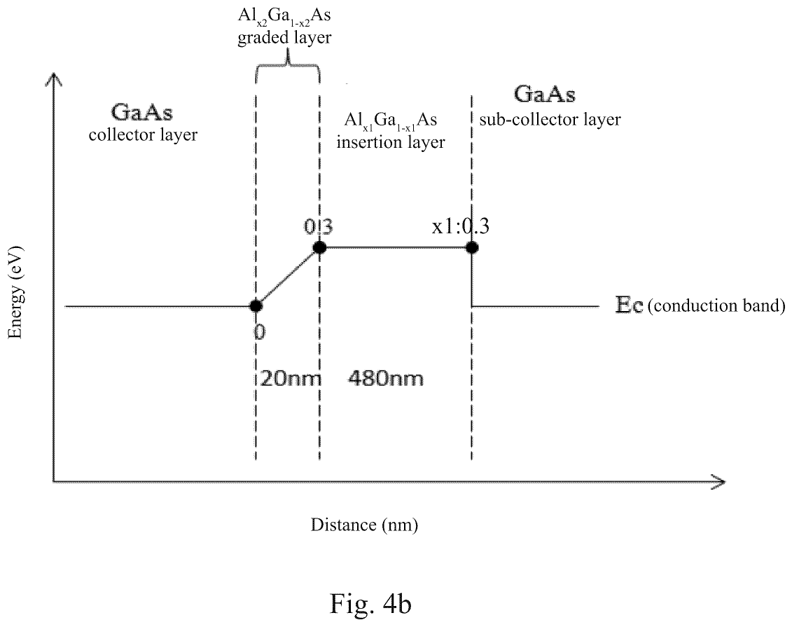

Referring to FIG. 4a, FIG. 4a is a comparison diagram showing the common emitter I-V characteristics of an HBT with the AlGaAs insertion layer and an HBT without the AlGaAs insertion layer. The emitter-base junction area Ae of these two HBTs are both 75*75 μm², the total thickness of the GaAs sub-collector layer is approximately 0.8 μm, and the n-type doping concentration is about 4×10¹⁸/cm³. The HBT with AlGaAs insertion layer is fabricated with reference to the U.S. Patent Publication Number 6806513 (hereinafter referred to as the 513 patent), and its conduction band configuration is depicted in FIG. 4b.

As shown in FIG. 4b, the GaAs collector layer has a thickness of 2.5 μm, with an n-type doping concentration of 7×10¹⁵/cm³. The thickness of the Alₓ₁Ga₁₋ₓ₁As insertion layer is 0.48 μm, wherein x1 is about 0.3, and the n-type doping concentration of the Alₓ₁Ga₁₋ₓ₁As insertion layer is 7×10¹⁵/cm³. The Alₓ₂Ga₁₋ₓ₂As graded layer with a thickness of 0.02 μm is provided between the Alₓ₁Ga₁₋ₓ₁As insertion layer with a thickness of 0.48 μm and the GaAs collector layer with a thickness of 2.5 μm, and the x2 of the Alₓ₂Ga₁₋ₓ₂As graded layer is graded from 0.3 to 0. Another HBT is without an insertion layer, in which the thickness of the GaAs collector layer is 3 μm, and the n-type doping concentration is 7×10¹⁵/cm³.

It is clear from FIG. 4a that when the HBT made with reference to the 513 patent is operated at a very low current density, the knee voltage of the HBT is already very large. Therefore, if the current density is increased to the normal operating current density of the PA, the knee voltage of the HBT made with reference to the 513 patent inevitably becomes larger, so it is difficult for the PA to be operated properly or the characteristics of the PA may seriously deteriorate.

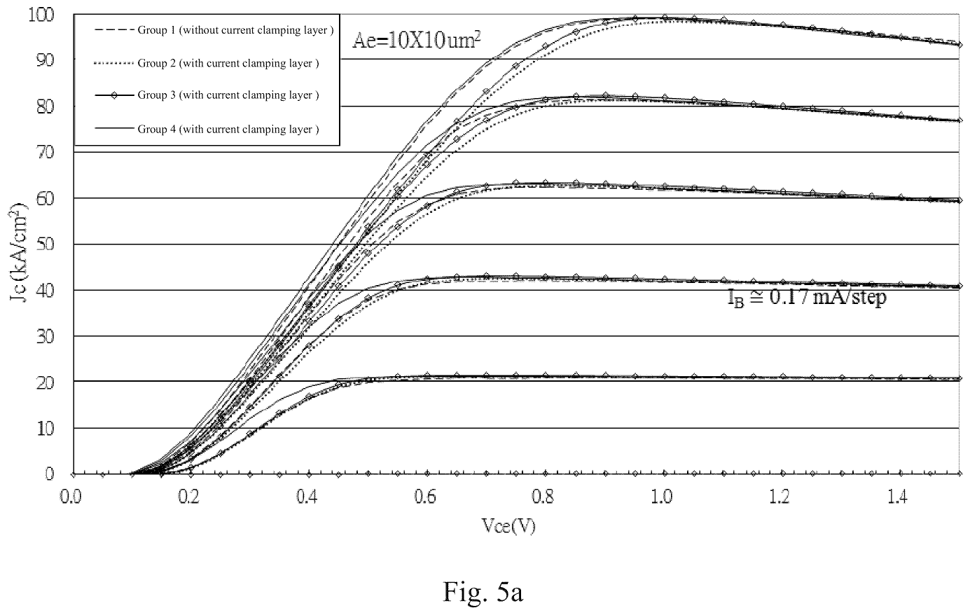

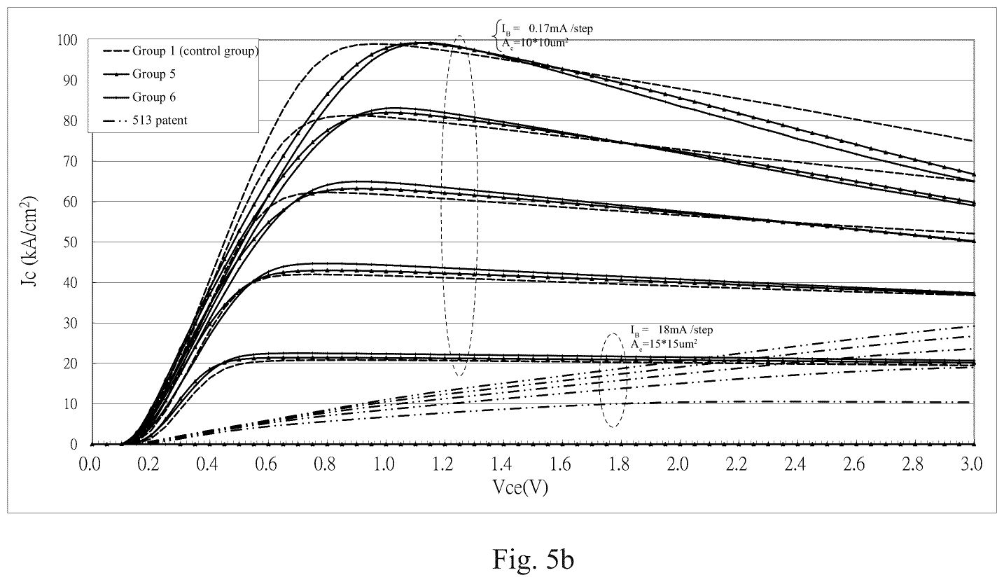

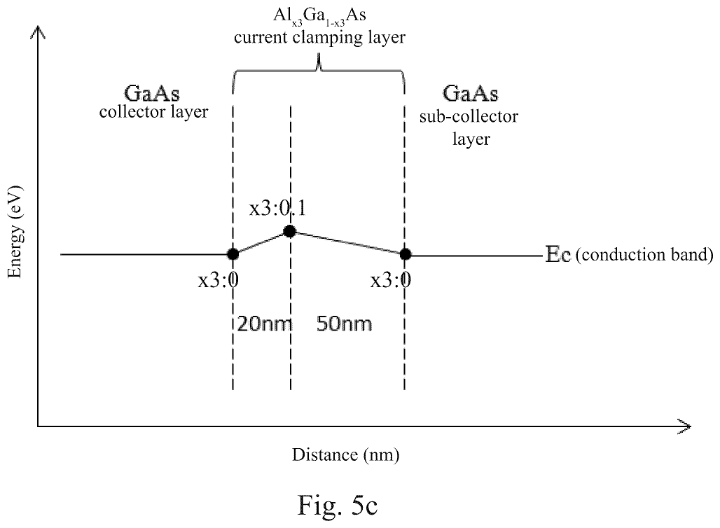

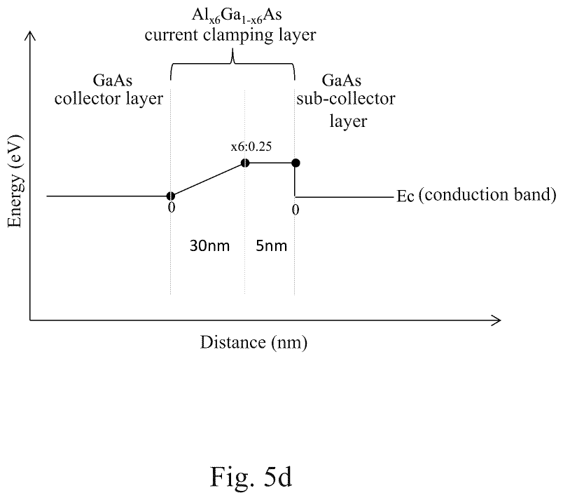

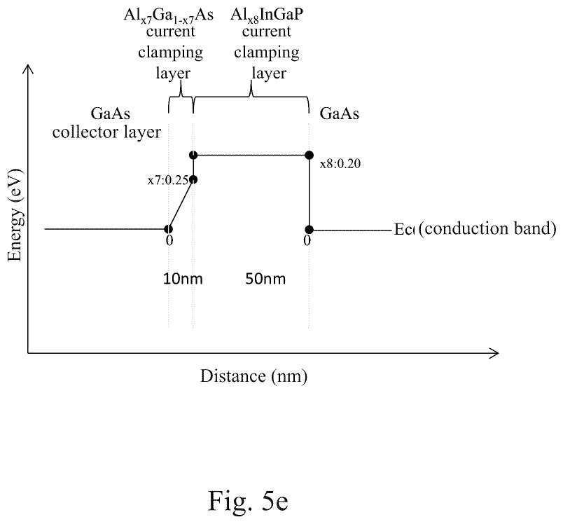

Referring to FIGS. 5a and 5b, FIGS. 5a and 5b are comparison diagram showing the common emitter I-V characteristics of seven different HBTs. The emitter-base junction area Ae of seven different HBTs is 10*10 μm². The HBT in group 1 (control group) does not have current clamping layer, that is, the GaAs collector layer is directly formed on the GaAs sub-collector layer. The total thickness of the GaAs sub-collector layer is about 0.8 μm, and its n-type doping concentration is about 4×10¹⁸/cm³; while the total thickness of the GaAs collector layer is about 1.47 μm, and the GaAs collector layer exhibits n-type doping concentration of approximately 5×10¹⁵/cm³ near the base layer, and approximately 1×10¹⁷/cm³ near the sub-collector layer.

The epitaxial structures of groups 2, 3, and 4 are the same as the epitaxial structure of FIG. 1a. The total thickness and n-type doping concentration of the GaAs sub-collector layers of groups 2, 3, and 4 are the same as those of the control group. The difference in structure between “groups 2, 3, and 4” and the control group is that, firstly, a current clamping layer is provided between the GaAs sub-collector layer and the GaAs collector layer in groups 2, 3, and 4. The total thickness of the current clamping layer in groups 2, 3, and 4 is about 0.07 μm (70 nm). In addition, the total thickness of the GaAs collector layers of Groups 2, 3, and 4 is about 1.4 m. In groups 2, 3, and 4, the collector layer exhibits n-type doping concentration of approximately 5×10¹⁵/cm³ near the base layer and approximately 1×10¹⁷/cm³ near the sub-collector layer.

FIG. 5c is a schematic diagram showing the conduction band of the Alₓ₃Ga₁₋ₓ₃As current clamping layer of group 2, wherein the maximum value of x3 is 0.1. The conduction band configuration of the Alₓ₄Ga₁₋ₓ₄As current clamping layer in groups 3 and Alₓ₅Ga₁₋ₓ₅As current clamping layer in groups 4 are similar to those of group 2, except that the maximum values of x4 and x5 are 0.3. In addition, the n-type doping concentrations of the current clamping layers of groups 2, 3, and 4 are about 2×10¹⁷/cm³, 3×10¹⁷/cm³, and 5×10¹⁷/cm³, respectively.

FIG. 5d is a schematic diagram of the conduction band of the Alₓ₆Ga₁₋ₓ₆As current clamping layer of group 5, wherein the maximum value of x6 is about 0.25. The Alₓ₆Ga₁₋ₓ₆As current clamping layer is provided between the GaAs sub-collector layer and the GaAs collector layer. The total thickness of the Alₓ₆Ga₁₋ₓ₆As current clamping layer is about 0.035 μm (35 nm). The n-type doping concentration of the Alₓ₆Ga₁₋ₓ₆As current clamping layer of group 5 is about 1×10¹⁸/cm³.

FIG. 5e is a schematic diagram of the conduction band of the Alₓ₇Ga₁₋ₓ₇As current clamping layer and the conduction band of the Alₓ₈InGaP current clamping layer of group 6. An Alₓ₇Ga₁₋ₓ₇As current clamping layer and an Alₓ₈InGaP current clamping layer are provided between the GaAs sub-collector layer and the GaAs collector layer. The thickness of the Alₓ₇Ga₁₋ₓ₇As current clamping layer is about 0.01 μm (10 nm), and the n-type doping concentration of the Alₓ₇Ga₁₋ₓ₇As current clamping layer is about 1×10¹⁸/cm³, wherein x7 is graded from 0.25 to 0. The thickness of the Alₓ₈InGaP current clamping layer is about 0.05 μm (50 nm), and the n-type doping concentration of the Alₓ₈InGaP current clamping layer is about 1×10¹⁷/cm³, wherein the bandgap of the Alₓ₈InGaP current clamping is constant, and x8 is about 0.2.

As shown in FIG. 5a and FIG. 5b, although group 4 is provided with a current clamping layer, the knee voltage of the HBT of group 4 is almost the same as the HBT without a current clamping layer. It can be seen that when the current clamping layer in the appropriate material composition ratio, high doping concentration, and thickness, it does not significantly impact the efficiency and RF characteristics of HBT or PA. As indicated by the experimental results from the ruggedness test, the PA's withstandable maximum output power is increased by about 1 dBm. From the characteristic curve of group 2, it is evident that when the aluminum composition and doping concentrations in the Alₓ₃Ga₁₋ₓ₃As current clamping layer are lower, the knee voltage of the HBT increases. Furthermore, the aluminum composition of the Alₓ₁Ga₁₋ₓ₁As current clamping layer is the same in Groups 3 and 4; However, due to the lower doping concentration in the Alₓ₄Ga₁₋ₓ₄As current clamping layer of Group 3's HBT, its knee voltage is higher than that of Group 4's HBT. From FIG. 5b, it is evident that the HBT made with reference to the 513 patent exhibits a significantly high knee voltage when operated at a low current density. As a result, it is difficult for HBT to be operated in the active region. Even if the HBT operates in the saturation region, its current density is very low. Consequently, the PA will struggle to operate properly, or the PA's characteristics will deteriorate significantly.

Based on the above, whether the current clamping layer is disposed within the collector layer or disposed between the collector layer and sub-collector layer, maintaining the PA's characteristics without degradation and enhancing its ruggedness is related to the design of the collector layer, current clamping layer or sub-collector layer in terms of the material, thickness, material composition ratio, doping concentration, or doping method (such as doping profile).

Any or some of the embodiments herein can also be used with the embodiments of the Taiwan Patent Number I727591, in which the current clamping layer is disposed in the emitter cap layer.

The above are only preferred embodiments for explaining the present invention, and are not intended to limit the present invention in any form. Therefore, any modification or change related to the present invention made under the same spirit of the invention should still be included in the intended protection scope of the present invention.

What is claimed is:

1. A heterojunction bipolar transistor structure, comprising:
a substrate;
a sub-collector layer on the substrate and comprising an n-type III-V group semiconductor material;
a collector layer on the sub-collector layer and comprising a III-V semiconductor material;
a base layer on the collector layer and comprising a p-type III-V group semiconductor material;
an emitter layer on the base layer and comprising an n-type III-V group semiconductor material;
an emitter cap layer on the emitter layer and comprising a III-V semiconductor material;
an ohmic contact layer on the emitter cap layer and comprising an n-type III-V semiconductor material; and
a current clamping layer disposed in the collector layer, in the sub-collector layer or interposed between the sub-collector layer and the collector layer, wherein an electron affinity of the current clamping layer is less than an electron affinity of an epitaxial layer on the current clamping layer.

2. The heterojunction bipolar transistor structure of claim 1, wherein the material of the sub-collector layer and the collector layer is GaAs.

3. The heterojunction bipolar transistor structure of claim 2, wherein the current clamping layer is interposed between the sub-collector layer and the collector layer, and the electron affinity of the current clamping layer is less than an electron affinity of the collector layer.

4. The heterojunction bipolar transistor structure of claim 2, wherein the current clamping layer comprises at least one material selected from the group consisting of AlₓGa₁₋ₓAs, AlGaAsN, AlGaAsP, AlGaAsSb, InAlGaAs, GaAsSb, InGaP, InAlGaP, GaAsPSb, and GaSbP, wherein x is 0.05 to 0.4.

5. The heterojunction bipolar transistor structure of claim 1, wherein the collector layer comprises a plurality of layers and the current clamping layer is one of the plurality of layers of the collector layer, and an electron affinity of a layer on the current clamping layer is greater than the electron affinity of the current clamping layer.

6. The heterojunction bipolar transistor structure of claim 1, wherein the current clamping layer is disposed in the sub-collector layer and adjacent to the collector layer.

7. The heterojunction bipolar transistor structure of claim 6, wherein a portion of the sub-collector layer is a GaAs layer and the GaAs layer is on the current clamping layer, and the electron affinity of the current clamping layer is less than an electron affinity of the GaAs layer.

8. The heterojunction bipolar transistor structure of claim 1, wherein the bandgaps of the current clamping layer comprises gradually-increasing bandgap, gradually-decreasing bandgap, constant bandgap, or combinations thereof.

9. The heterojunction bipolar transistor structure of claim 1, wherein an n-type doping concentration of the current clamping layer is from 8×10¹⁵/cm³ to 2×10¹⁸/cm³ and a thickness of the current clamping layer is from 100 Å to 10000 Å.
